(19) United States
(12) Patent Application Publication
(10) Pub. No.: US 2013/0256010 A1
(43) Pub. Date: Oct. 3, 2013

(54) METHOD OF MANUFACTURING MULTILAYER PRINTED CIRCUIT BOARD AND MULTILAYER PRINTED CIRCUIT BOARD MANUFACTURED VIA THE SAME

(71) Applicant: SAMSUNG ELECTRO-MECHANICS CO., LTD., Suwon (KR)

(72) Inventors: Jae Youb JUNG, Suwon (KR); Yang Je Lee, Suwon (KR)

(73) Assignee: SAMSUNG ELECTRO-MECHANICS CO., LTD., SUWON (KR)

(21) Appl. No.: 13/793,618

(22) Filed: Mar. 11, 2013

(30) Foreign Application Priority Data
Mar. 29, 2012 (KR) 10-2012-0032431

(51) Int. Cl. H05K 3/46; H05K 1/11; H05K 1/09

(52) U.S. Cl. CPC H05K 3/4644; H05K 1/09; H05K 1/115
USPC 174/257; 427/97.2; 427/555

(57) ABSTRACT

Disclosed herein are a method of manufacturing a multilayer printed circuit board (PCB), a via which is an inner via hole (IVH) having a stable structure so as to easily form a fine pattern, thereby thinning a product, and a multilayer PCB manufactured via the same. The method includes preparing a base substrate including copper foils formed on opposite surfaces or a single surface of the base substrate; forming an insulating layer on the base substrate via a coating process; processing a via hole through the insulating layer formed on the base substrate up to the base substrate; performing fill plating on the via hole; and stacking at least one circuit layer on a metal layer that is formed via the fill plating.

### CROSS REFERENCE(S) TO RELATED APPLICATIONS

This application claims the benefit under 35 U.S.C. Section 119 of Korean Patent Application Serial No. 10-2012-0032431, entitled “Method of Manufacturing Multilayer Printed Circuit Board and Multilayer Printed Circuit Board Manufactured via the Same” filed on Mar. 29, 2012, which is hereby incorporated by reference in its entirety into this application.

### BACKGROUND OF THE INVENTION

1. Technical Field

The present invention relates to a method of manufacturing a multilayer printed circuit board and a multilayer printed circuit board manufactured via the same, and more particularly, to a method of forming an inner via hole (IVH).

2. Description of the Related Art

Recently, printed circuit boards (PCBs) accommodated in an electronic device have been designed more complex due to transmission and receipt of a large amount of data from the Internet, moving pictures, or the like as well as the portability and high performance of electronic devices, and needs for high-density and small-sized circuits have gradually increased. Accordingly, since PCBs accommodated in an electronic device have been thinned and miniaturized, a line width of wirings of PCBs is reduced in order to achieve various functions of PCBs and PCBs are manufactured to have a multilayer structure instead of a single layer structure.

In a multilayer PCB, a via hole is formed through an insulating layer in order to connect layers to each other.

The via hole is formed as follows. First, the insulating layer is coated on a metal layer having a circuit pattern formed thereon and the via hole is formed in an appropriate position of the coated insulating layer by using a drill. Then, metal is filled in the via hole by using a plating process or a filling process of a conductive material so as to connect layers to each other.

With regard to a multilayer PCB, there is a need to process an inner via hole (IVH) for connecting all layers to each other.

An IVH technology is used to manufacture a multilayer PCB that requires high-density stacking. In this case, an IVH is formed by filling a conductive material in a via hole formed through adjacent layers so as to connect the adjacent layers to each other.

With regard to formation of an IVH, Korean Patent Laid-Open Publication No. 10-2007-0070225 (hereinafter, referred to as the related art document) discloses a technology in which external stress such as shock is prevented when an insulating substrate is dropped so as to prevent the insulating substrate from being easily bent and to prevent a conductive circuit from cracking or being disconnected.

With reference to FIG. 10 of the related art document, the technology disclosed in the related art document will be described in detail. It is confirmed that, like in other conventional methods of manufacturing a PCB, a via hole is formed from a base substrate as a core layer and then an IVH is completed by processing the via hole for each build-up process.

A process of forming an IVH in a conventional method of manufacturing a PCB will now be described in detail. As a first process, an opening is formed in a base substrate (‘copper cladded laminate (CCL)’), on which a copper foil is formed, via window etching. As a second process, a via hole is processed in the opening via a drilling process using a CO₂ laser or the like. As a third process, a conductive material is filled in the via hole via fill plating. As a fourth process, a circuit pattern is formed on the copper foil. As a fifth process, an insulating layer, and a plating layer are stacked on the copper cladded laminate (CCL). As a sixth process, an opening is formed via window etching. As a seventh process, a via hole is processed by irradiating a laser beam through the opening. As an eighth process, a conductive material is filled in the via hole via fill plating. Lastly, as a ninth process, a plating layer is etched to form a circuit pattern. In addition, according to the number of required layers, the IVH is formed to have a stack via structure by repeating the fifth through ninth processes.

Likewise, when an IVH is formed by using a conventional method, a via hole is processed from a base substrate, fill plating is performed, and then these processes are repeated several times whenever the number of layers is increased, thereby increasing a lead time taken to manufacture a product and increasing manufacturing costs.

A rigid-flexible PCB uses a thin base substrate formed of a flexible material. Thus, since the strength of structurally supporting the rigid-flexible PCB is weak due to the thin thickness and flexible material of the rigid-flexible PCB, a via hole collapses easily during formation of the via hole. Accordingly, the thickness of a base substrate cannot help but increase in order to process a stable via hole, which adversely affects sliming of a product.

### RELATED ART DOCUMENT

### Patent Document

(Patent Document 1) Korean Patent Laid-Open Publication No. 10-2007-0070225

### SUMMARY OF THE INVENTION

An object of the present invention is to provide a method of manufacturing a printed circuit board (PCB) that easily forms a fine pattern and reduces a manufacturing lead time and manufacturing costs.

According to an exemplary embodiment of the present invention, there is provided a method of manufacturing a multilayer printed circuit board (PCB), including: preparing a base substrate including copper foils formed on opposite surfaces or a single surface of the base substrate; forming an insulating layer on the base substrate via a coating process; processing a via hole through the insulating layer formed on the base substrate up to the base substrate; performing fill plating on the via hole; and stacking at least one circuit layer on a metal layer that is formed via the fill plating.

The method may further include, after the preparing of the base substrate, etching a copper coil formed on a first surface of the base substrate such that the copper coil remains on only a second surface of the base substrate, in which the via hole is to be formed.

The base substrate may be formed of a flexible or rigid material.

When the base substrate is formed of the flexible material, the base substrate may have a thickness of 5 to 30 μm.

When the base substrate is formed of the rigid material, the base substrate may have a thickness of 10 to 50 μm.

The method may further include forming a seed layer on the insulating layer that is formed during the forming of the insulating layer.

The method may further include, during the processing of the via hole, forming an opening by window-etching a portion of the seed layer, in which the via hole is to be formed.

The method may further include, after the preparing of the base substrate, forming a circuit pattern on the copper foil formed on the base substrate.

The method may further include, after the fill plating is performed on the via hole, forming a circuit pattern on the metal layer that is formed via the fill plating.

The stacking of the at least one circuit layer may include forming an insulating layer covering the metal layer via a coating process; forming a seed layer on the insulating layer; forming a via hole through the insulating layer; performing fill plating; and forming a circuit pattern on a metal layer that is formed via the fill plating.

The processing of the via hole may be performed via a laser process or a router process.

The circuit pattern may be formed by using any one of an additive process, a subtractive process, and a semi-additive process.

According to another exemplary embodiment of the present invention, there is provided a multilayer printed circuit board (PCB) including a base substrate having circuit patterns formed on opposite surfaces of the base substrate and at least one circuit layer formed on upper and lower surfaces of the base substrate, including a first via formed through the base substrate and the at least one circuit layer stacked on a first surface of the base substrate; a second via formed through the at least one circuit layer stacked on a second surface of the base substrate; and a copper foil disposed on an upper or lower surface of the base substrate and disposed between the first via and the second via.

The first and second vias and the copper foil may include at least one selected from copper (Cu), silver (Ag), palladium (Pd), aluminum (Al), nickel (Ni), titanium (Ti), gold (Au), and platinum (Pt), or a mixture including at least two thereof.

At least one circuit layer may include an insulating layer having a circuit pattern formed on an upper surface thereof.

### BRIEF DESCRIPTION OF THE DRAWINGS

FIGS. 1A through 1J are cross-sectional views for describing a method of manufacturing a multilayer printed circuit board (PCB) according to an embodiment of the present invention; and

FIG. 2 is a cross-sectional view of a multilayer PCB manufactured by using a manufacturing method, according to an embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the description denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an acting effect of exemplary embodiments of the present invention will be described in more detail with reference to the accompanying drawings.

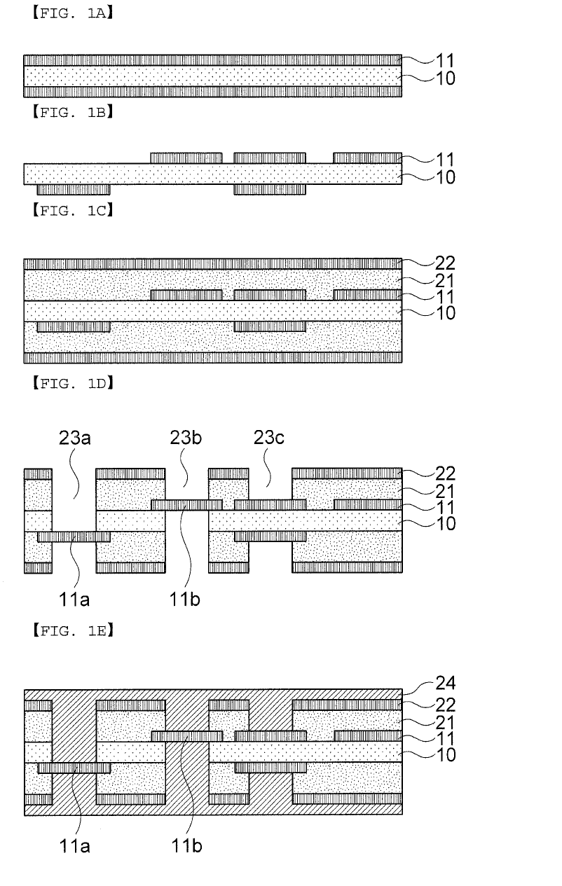

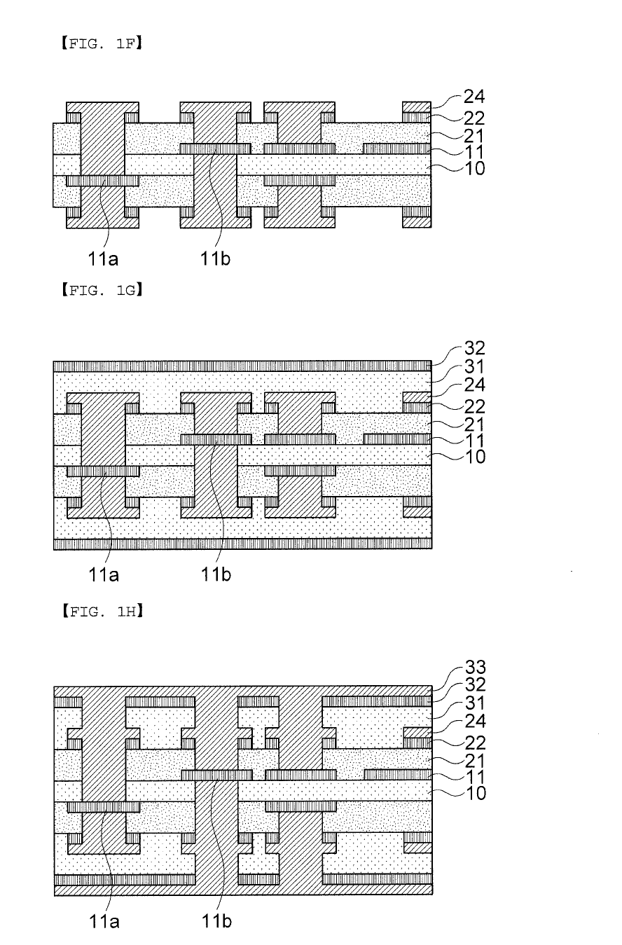

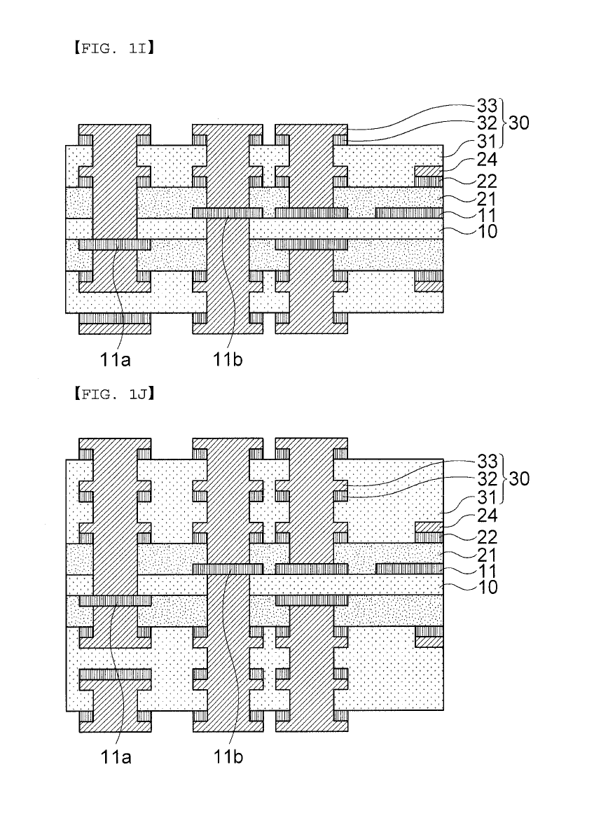

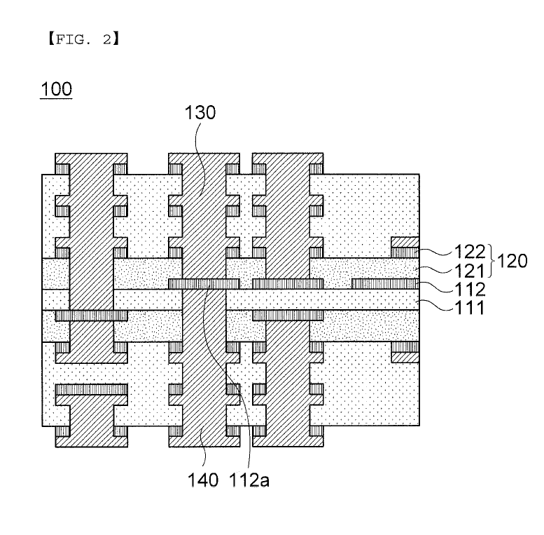

FIGS. 1A through 1J are cross-sectional views for describing a method of manufacturing a multilayer printed circuit board (PCB) according to an embodiment of the present invention. In the following description with reference to FIG. 1, a detailed description of unnecessary configurations other than configurations of the present invention will be omitted when it may make the subject matter of the present invention unclear.

In the method of manufacturing the multilayer PCB according to the present embodiment, a base substrate 10 is prepared, wherein copper foils 11 are formed on opposite surfaces or a single surface of the base substrate 10, as shown in FIG. 1A.

In this case, the base substrate 10 is a core layer in the multilayer PCB. When the base substrate 10 is used in a rigid PCB, the base substrate 10 may be formed of a rigid material. When the base substrate 10 is used in a rigid-flexible PCB, the base substrate 10 may be formed of a flexible material. For example, the base substrate 10 may be formed of a material including an epoxy-based resin such as FR-4 or bismaleimide triazine (BT), prepreg, an Ajinomoto build up film (ABF), or the like.

In detail, when the base substrate 10 is formed of a rigid material, the base substrate 10 may be set to have a thickness of 10 to 50 μm. When the base substrate 10 may be formed of a flexible material, the base substrate 10 may be set to have a thickness of 5 to 30 μm. As such, the reason why the thickness of the base substrate 10 is restricted to a predetermined range will be described in the section for the effect of the invention. When the thickness of the base substrate 10 is set within the above range, the effect of the invention may be further exhibited only. Thus, the thickness of the base substrate 10 is not limited to the above range.

The copper foils 11 formed on opposite surfaces or a single surface of the base substrate 10 may be formed of not only copper (Cu), but also of at least one selected from silver (Ag), palladium (Pd), aluminum (Al), nickel (Ni), titanium (Ti), gold (Au), and platinum (Pt), which have excellent electrical properties, or a mixture including at least two thereof.

Then, as shown in FIG. 1B, a circuit pattern is formed on the copper foils 11 formed on opposite surfaces or a single surface of the base substrate 10.

The circuit pattern may be formed by using any one of an additive process, a subtractive process, and a semi-additive process. These technologies are well known to the art to which the present invention pertains, and thus, a detailed description thereof will be omitted herein.

Then, as shown in FIG. 1C, an insulating layer 21 is formed on the base substrate 10 via a coating process.

A lower circuit pattern is covered by the insulating layer 21 and an upper circuit pattern is formed on an upper surface of the insulating layer 21. The insulating layer 21 electrically insulates interlayer circuit patterns from each other. The insulating layer 21 may be formed of any one of epoxy, a phenolic resin, prepreg, a polyimide film, and an ABF film.

After the insulating layer 21 is formed via a coating process, a seed layer 22 for plating may be formed on an upper surface of the insulating layer 21. The seed layer 22 is an electrolytic plating lead through which fill plating that will be described below is performed. Thus, the seed layer 22 may be formed of at least one selected from Cu, Ag, Pd, Al, Ni, Ti, Au, and Pt, which have excellent electrical properties, or a mixture including at least two thereof, like the copper foils 11 formed on opposite surfaces or a single surface of the base substrate 10.

Then, as shown in FIG. 1D, via holes 23a, 23b, and 23c formed through both the base substrate 10 and the insulating layer 21 formed on the base substrate 10, or both the insulating layer 21 and the base substrate 10 formed below the insulating layer 21 are processed.

That is, as shown in FIG. 1D, the via holes 23a and 23b is formed through not only the insulating layer 21, but also through the base substrate 10 formed below the insulating layer 21. Thus, the via holes 23a and 23b correspond to inner via holes (IVHs). In addition, the via hole 23c is formed through the insulating layer 21 only.

The via holes 23a, 23b, and 23c may be processed via a drilling process such as a computer numerical control (CNC) drill, and CO₂ or Yag laser drill, or the like. Prior to the drilling process, openings are formed by window-etching portions of the seed layer 22, in which the via holes 23a, 23b, and 23c are to be formed, thereby facilitating the processing of the via holes 23a, 23b, and 23c.

During the processing of the via holes 23a and 23b as IVHs, a copper foil formed on a first surface may be etched such that a copper foil may be formed on only a second surface, with regard to portions of the base substrate 10, in which the via holes 23a and 23b as IVHs are to be formed, and thus the copper foil 11 formed on the base substrate 10 may serve as a stopper.

That is, as shown in FIG. 1D, a copper foil formed on a first surface of the base substrate 10 is etched such that only a copper foil 11a may remain on only a second surface of the base substrate 10, in which the via hole 23a as an IVH is to be formed. In addition, the first surface of the base substrate 10 is etched such that only a copper foil 11b may remain on the second surface of the base substrate 10, in which the via hole 23b as an IVH is to be formed.

The copper foils 11a and 11b may be formed on an upper surface and a lower surface of the base substrate 10. For example, the copper foil 11a may be formed on the lower surface of the base substrate 10. The copper foil 11b may be formed on the upper surface of the base substrate 10.

The copper foils 11a and 11b serve as a stopper during a drilling process. For example, with regard to the copper foil 11a, the drilling process is performed on the insulating layer 21 formed on the base substrate 10 to drill up to the base substrate 10 and the drilling process is performed on the insulating layer 21 formed below the base substrate 10 to drill up to the insulating layer 21 only. As a result, IVHs is formed across the copper foil 11a. In addition, interlayer connection between upper and lower portions of the base substrate 10 is obtained via fill plating that will be described below.

A conventional method of forming an IVH will now be described. An opening is formed by window-etching a base substrate on which a copper foil is formed (first process), a via hole is formed by irradiating a laser beam to the opening (second process), a conductive material is filled in the via hole via fill plating (third process), and then a circuit pattern is formed on the copper foil (fourth process). In addition, whenever the number of circuit layers is increased on the base substrate, a process including stacking an insulating layer and a metal layer on the base substrate, forming an opening via window etching, processing a via hole by irradiating a laser beam through the opening, filling a conductive material in the via hole via fill plating, and etching a metal layer to form a circuit pattern is repeated, thereby completing IVHs.

Likewise, conventionally, the via hole is processed from the base substrate and then fill plating is performed. With respect to each respective layer formed on the base substrate, a process including forming an opening, processing a via hole, and fill plating is repeated.

However, according to the present embodiment, in a method of manufacturing a multilayer PCB, a copper foil formed on a surface of a base substrate is etched to remain in an appropriate position and a drilling process is performed when an insulating layer is already formed on the base substrate so as to form an IVH that is formed through both the base substrate and the insulating layer. Accordingly, compared to the conventional method, the first through third processes may be omitted. Thus, a manufacturing lead time and manufacturing costs may be reduced.

In general, a rigid-flexible PCB uses a thin base substrate formed of a flexible material. Thus, when a vial hole is formed in the thin base substrate, since the strength of structurally supporting the PCB is weak due to the thin thickness and flexible material of the PCB, it is difficult to process a stable via hole by using a conventional method.

However, according to the present embodiment, in a method of manufacturing a PCB, since a drilling process is performed when an insulating layer is already formed on a base substrate, an IVH may be formed to have a predetermined shape without collapsing not only in a rigid PCB using a base substrate with a thickness of 10 to 50 μm and formed of a rigid material, but also in a rigid-flexible PCB using a base substrate with a small thickness of 5 to 30 μm and formed of a flexible material. Thus, when a PCB is manufactured by using the manufacturing method according to the present embodiment, the PCB may be easily thinned and miniaturized.

Then, as shown in FIG. 1E, electrolytic fill plating is performed by using the seed layer 22 as a plating lead to fill copper (Cu) in the via holes 23a, 23b, and 23c. In this case, metal filled via electrolytic fill plating may be, for example, not only Cu, but also at least one selected from Ag, Pd, Al, Ni, Ti, Au, and Pt, which have excellent electrical properties, or a mixture including at least two thereof.

Likewise, the via holes 23a and 23b may be filled with metal via the fill plating to connect circuits between upper and lower portions of the base substrate 10 to each other and to form a metal layer 24 on the insulating layer 21 (in more detail, the seed layer 22).

Then, as shown in FIG. 1F, a circuit pattern is formed on the metal layer 24 formed via fill plating. The circuit pattern formed on the metal layer 24 may be formed by using any one of an additive process, a subtractive process, and a semi-additive process, as described above.

Then, at least one circuit layer 30 (see FIG. 1I) is stacked on the metal layer 24.

In this case, a single circuit layer 30 collectively refers to an insulating layer and a metal layer formed on the insulating layer. First, as shown in FIG. 1G, an insulating layer 31 is formed to cover the metal layer 24 via a coating process and then a seed layer 32 is formed on the insulating layer 31.

Then, as shown in FIG. 1H, a metal layer 33 is formed via fill plating. As shown in FIG. 1I, a circuit pattern may be formed on the metal layer 33 by using any one of an additive process, a subtractive process, and a semi-additive process to form a single circuit layer 30.

If necessary, a plurality of circuit layers 30 may be formed, as shown in FIG. 1J. In this case, when the circuit layer 30 is stacked, a via hole connected to the via holes 23a, 23b, and 23c may be processed in the insulating layer 31 included in the circuit layer 30 to have a stack via structure.

Hereinafter, a multilayer PCB manufactured by using a manufacturing method will be described with regard to an exemplary embodiment of the present invention.

FIG. 2 is a cross-sectional view of a multilayer PCB 100 manufactured by using a manufacturing method, according to an embodiment of the present invention.

Referring to FIG. 2, the multilayer PCB 100 manufactured by using the manufacturing method according to the present embodiment may include a base substrate 111 including a circuit pattern 112 formed on opposite surfaces thereof, and at least one circuit layer 120 formed on upper and lower surfaces of the base substrate 111.

In addition, the multilayer PCB 100 may include a first via 130 formed through both the base substrate 111 and the circuit layer 120 stacked on the upper surface of the base substrate 111, and a second via 140 formed through the circuit layer 120 formed on the lower surface of the base substrate 111. In addition, the multilayer PCB 100 may include a copper foil 112a disposed between the first via 130 and the second via 140.

In this case, a single circuit layer 120 covers the circuit pattern 112 formed below the circuit layer 120 and refers to an insulating layer 121 including a circuit pattern 112 formed on an upper surface thereof. In addition, the circuit pattern 112 formed on the base substrate 111 and the circuit pattern 112 included in the circuit layer 120 refer to a circuit that is formed by etching a metal layer to have a predetermined pattern by using any one of an additive process, a subtractive process, and a semi-additive process.

The copper foil 112a is a portion that is not etched in order to electrically connect the first via 130 and the second via 140 to each other when the circuit pattern 112 is formed on copper foils formed on opposite surfaces of the base substrate 111. The copper foil 112a may electrically connect the first via 130 and the second via 140 to each other and also may serve as a stopper during formation of a via hole.

The copper foil 112a may be disposed on the upper or lower surface of the base substrate 111. When the copper foil 112a is disposed on the upper surface of the base substrate 111, a via hole for the second via 140 is processed through both an insulating layer formed below the base substrate 111 and the base substrate 111, and a via hole for the first via 130 is processed through only an insulating layer formed on the base substrate 111.

On the other hand, when the copper foil 112a is disposed on the lower surface of the base substrate ill, the via hole for the second via 140 is processed through only the insulating layer formed below the base substrate 111, and a via hole for the first via 130 is processed through both the insulating layer formed on the base substrate 111 and the base substrate 111.

Likewise, the copper foil 112a is disposed between the first via 130 and the second via 140 to electrically connect the first via 130 and the second via 140 to each other. Thus, the first and second vias 130 and 140 and the copper foil 112a may be formed of at least one selected from Cu, Ag, Pd, Al, Ni, Ti, Au, and Pt, which have excellent electrical properties, or a mixture including at least two thereof.

According to the present embodiment, in a method of manufacturing a multilayer PCB, a copper foil formed on a surface of a base substrate is etched to remain in an appropriate position and a drilling process is performed when an insulating layer is already formed on the base substrate so as to form an IVH that is formed through both the base substrate and the insulating layer. Accordingly, compared to a conventional method, a predetermined process may be omitted. Thus, a manufacturing lead time and manufacturing costs may be reduced.

In addition, since a drilling process is performed when an insulating layer is already formed on a base substrate, an IVH may be formed to have a stable structure not only in a rigid PCB using a base substrate formed of a rigid material, but also in a rigid-flexible PCB using a thin base substrate formed of a flexible material. Thus, when a PCB is manufactured by using the manufacturing method according to the present embodiment, the PCB may be easily thinned and miniaturized.

The above detailed description exemplifies the present invention. Further, the above contents just illustrate and describe preferred embodiments of the present invention and the present invention can be used under various combinations, changes, and environments. That is, it will be appreciated by those skilled in the art that substitutions, modifications and changes may be made in these embodiments without departing from the principles and spirit of the general inventive concept, the scope of which is defined in the appended claims and their equivalents. Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Therefore, the detailed description of the present invention does not intend to limit the present invention to the disclosed embodiments. Further, it should be appreciated that the appended claims include even another embodiment.

What is claimed is:

1. A method of manufacturing a multilayer printed circuit board (PCB), comprising:
preparing a base substrate including copper foils formed on opposite surfaces or a single surface of the base substrate;
forming an insulating layer on the base substrate via a coating process;
processing a via hole through the insulating layer formed on the base substrate up to the base substrate;
performing fill plating on the via hole; and
stacking at least one circuit layer on a metal layer that is formed via the fill plating.

2. The method according to claim 1, further comprising, after the preparing of the base substrate, etching a copper coil formed on a first surface of the base substrate such that the copper coil remains on only a second surface of the base substrate, in which the via hole is to be formed.

3. The method according to claim 1, wherein the base substrate is formed of a flexible or rigid material.

4. The method according to claim 3, wherein, when the base substrate is formed of the flexible material, the base substrate has a thickness of 5 to 30 μm.

5. The method according to claim 3, wherein, when the base substrate is formed of the rigid material, the base substrate has a thickness of 10 to 50 μm.

6. The method according to claim 1, further comprising forming a seed layer on the insulating layer that is formed during the forming of the insulating layer.

7. The method according to claim 6, further comprising, during the processing of the via hole, forming an opening by window-etching a portion of the seed layer, in which the via hole is to be formed.

8. The method according to claim 1, further comprising, after the preparing of the base substrate, forming a circuit pattern on the copper foil formed on the base substrate.

9. The method according to claim 1, further comprising, after the performing fill plating on the via hole, forming a circuit pattern on the metal layer that is formed via the fill plating.

10. The method according to claim 1, wherein the stacking of the at least one circuit layer includes:
forming an insulating layer covering the metal layer via a coating process;
forming a seed layer on the insulating layer;
forming a via hole through the insulating layer;
performing fill plating; and
forming a circuit pattern on a metal layer that is formed via the fill plating.

11. The method according to claim 1, wherein the processing of the via hole is performed via a laser process or a router process.

12. The method according to claim 8, wherein the circuit pattern is formed by using any one of an additive process, a subtractive process, and a semi-additive process.

13. The method according to claim 9, wherein the circuit pattern is formed by using any one of an additive process, a subtractive process, and a semi-additive process.

14. A multilayer printed circuit board (PCB) including a base substrate having circuit patterns formed on opposite surfaces of the base substrate and at least one circuit layer formed on upper and lower surfaces of the base substrate, comprising:
a first via formed through the base substrate and the at least one circuit layer stacked on a first surface of the base substrate;
a second via formed through the at least one circuit layer stacked on a second surface of the base substrate; and
a copper foil disposed on an upper or lower surface of the base substrate and disposed between the first via and the second via.

15. The multilayer PCB according to claim 14, wherein the first and second vias and the copper foil include at least one selected from copper (Cu), silver (Ag), palladium (Pd), aluminum (Al), nickel (Ni), titanium (Ti), gold (Au), and platinum (Pt), or a mixture comprising at least two thereof.

16. The multilayer PCB according to claim 14 wherein the at least one circuit layer includes an insulating layer having a circuit pattern formed on an upper surface thereof.
